(19) United States
(12) Patent Application Publication
(10) Pub. No.: US 2006/0141728 A1
(43) Pub. Date: Jun. 29, 2006

(54) Formation of junctions and silicides with reduced thermal budget

(75) Inventor: Bartlomiej Jan Pawlak, Leuven (BE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., EINDHOVEN (NL)

(21) Appl. No.: 10/559,069

(22) PCT Filed: May 19, 2004
(86) PCT No.: PCT/IB04/50753

§ 371 Date: Nov. 30, 2005

(30) Foreign Application Priority Data
Jun. 3, 2003 (EP) 03101599.3

(51) Int. Cl. H01L 21/336

(52) U.S. Cl. 438/303

(57) ABSTRACT

Method of formation of a metal-silicide layer (12, 13, 14, 18, 19) an a semiconductor substrate (1), the semiconductor substrate (1) including at least a dopant region (5); the dopant region (5) including an ultra-shallow junction region; the method including as a first step at least one impurity implantation process (IB dopant) for forming the dopant region (5); the method including as a second step at least one metal implantation process (IB metal) for forming the metal-silicide layer (12, 13, 18, 19) an the dopant region (5), and the method including, as a third step carried out after the first and the second step, a low-temperature annealing process wherein simultaneously the dopant region (5) is activated and the metal-silicide layer (12, 13, 14, 18, 19) is formed.

The present invention relates to a method of manufacturing a semiconductor device comprising the step of forming a metal silicide for use in micro-electronic manufacturing applications.

To obtain higher device densities and/or higher operation speeds in many types of micro-electronic devices (integrated circuits), the design of new generations of such devices shows a tendency to use structural elements such as MOSFET transistors which occupy a smaller part of a chip area and also have a shallower depth than in previous device generations.

In newer device generations, the junctions in a MOSFET are reduced to a relatively shallow depth. Typically, in a first metallization level the junctions, i.e. source and drain regions, are provided with a conducting layer on top of them for electrical connections. Preferably, metal silicide is used as metallization since silicidation by a self-aligned formation process allows a relatively simple definition of the conducting elements.

During the formation of the metallization of the junctions simultaneously the gate conduction region of the MOSFET is covered by the same conducting metal silicide.

From U.S. Pat. No. 6,294,434 (Tseng) it is known to use an implantation process to deposit a suitable metal in the top surface of the junctions, which metal reacts to a metal-silicide in a subsequent annealing process with silicon in the junction and gate regions (and other silicon containing regions) exposed during the implantation process. In a first anneal, the junction and gate regions obtain a metal-silicide layer. Then, a cleaning process is applied to remove unreacted metal. Finally, a second anneal is applied to reduce the resistance of the metal silicide.

For IC designs with ultra-shallow junctions, however, in such a fabrication process the annealing processes for formation of the silicide layer may adversely affect the dopant profiles in the junction regions. The risk of deactivation of junctions due to (excess) thermal exposure may be appreciable and the yield of a manufacturing process for ICs of such a design may be affected. Consequently, the process windows are typically relatively narrow and need to be employed with great care to avoid any negative influence on the devices to be created.

It is an object of the present invention to provide a method of manufacturing a semiconductor device comprising the step of forming a metal silicide which does not adversely affect the properties of devices having ultra-shallow junctions.

This object is achieved by a process as defined in the preamble of claim 1, characterized in that the method is arranged to carry out after the first and the second step: as a third step a low-temperature annealing process wherein simultaneously the dopant region is activated and the metal-silicide layer is formed.

In the present invention, the activation of the junction regions and the silicide regions is performed in a single annealing process by solid phase epitaxial regrowth. Advantageously, simultaneous activation of the junction regions and formation of silicide will eliminate the deactivation of the ultra-shallow junction regions due to the thermal budget involved in additional annealing processes for silicide formation in the prior art.

Also, the single process advantageously reduces the number of processing steps in the fabrication process of micro-electronic devices with ultra-shallow junctions of the type as described above.

Moreover, the present invention provides good control of the silicide penetration depth due to the relatively low annealing temperature which causes the diffusion coefficients to be fairly low.

Furthermore, the present invention provides the possibility of a free selection of metal for silicide formation, in particular metals which form a silicide with a high stoichiometric silicon-metal ratio, such as a metal-di-silicide, may be preferred.

Additionally, by selection of a metal for implantation in relation to the conductivity type of the junction, the method according to the present invention provides that the work function can be matched for each junction in relation to its conductivity type and its respective dopant level.

Further, the present invention relates to a semiconductor device on a semiconductor substrate comprising a dopant region comprising an ultra-shallow junction, wherein the semiconductor device is manufactured by a method of formation of a metal-silicide layer as described above.

For the purpose of teaching the invention, preferred embodiments of the method and devices of the invention are described below. It will be appreciated by the person skilled in the art that other alternative and equivalent embodiments of the invention can be conceived and reduced to practice without departing form the true spirit of the invention, the scope of the invention being limited only by the appended claims.

Below, the invention will be explained with reference to some drawings, which are intended for illustration purposes only.

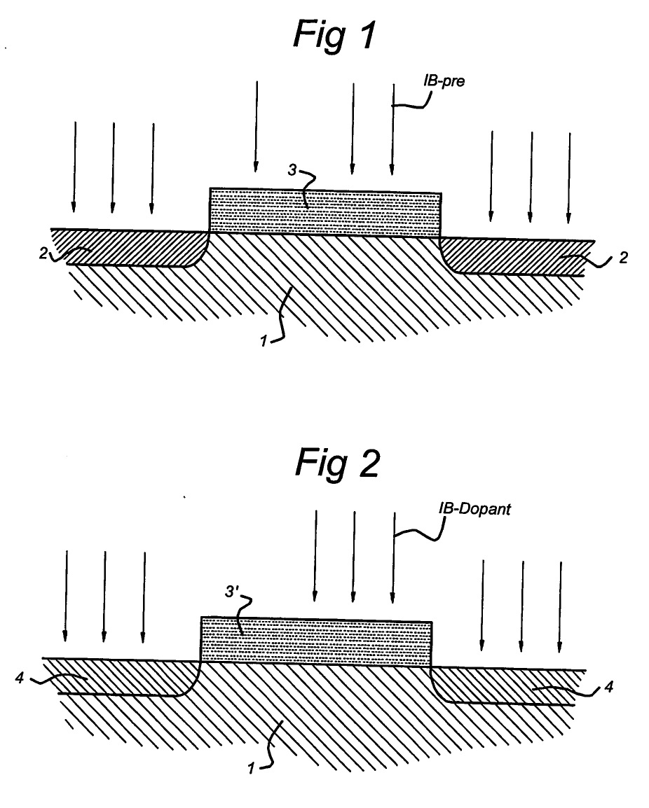

FIG. 1 shows schematically a cross-section of a semiconductor device during a first process in accordance with the method of the present invention;

FIG. 2 shows schematically a cross-section of a semiconductor device during a second process according to the present invention;

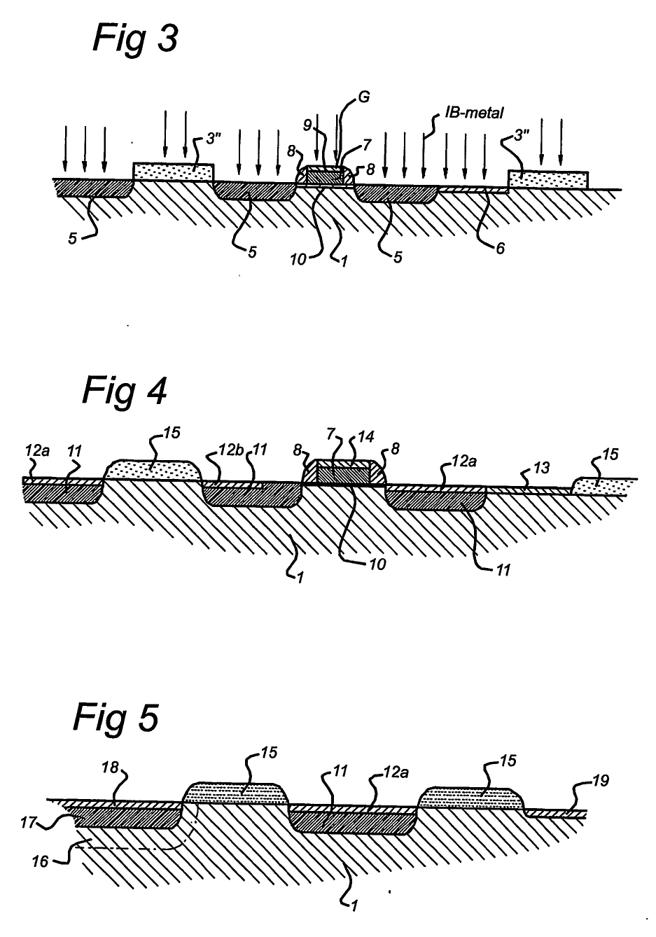

FIG. 3 shows schematically a cross-section of a semiconductor device during a third process according to the present invention;

FIG. 4 shows schematically a cross-section of a semiconductor device after a fourth process according to the present invention;

FIG. 5 shows schematically a cross-section of a semiconductor device in a further embodiment according to the present invention.

The present invention relates to the fabrication of micro-electronic devices which comprise ultra-shallow junctions and a silicide layer covering such junctions. FIG. 1 shows schematically a cross-section of a semiconductor device during a first process in accordance with the method of the present invention.

On a semiconductor substrate 1, such as a monocrystalline silicon wafer or a silicon-on-insulator substrate, the regions 2 where a junction will be formed are prepared in a first process. After definition of a mask 3 which delineates the area of the regions 2, a pre-amorphisation process of the regions 2 is performed. The pre-amorphisation process is done by ion-beam implantation by an ion beam IB_pre. The ion beam IB_pre is schematically indicated by arrows.

As ion source material Ge, GeF₂ or Si may be used. However, other elements may also be used such as heavy noble elements Ar, and Xe.

Typical parameters for a pre-amorphisation process are, e.g., for Ge a beam acceleration energy in the range 2-30 keV, with a dose of 2×10¹⁴-5×10¹⁵ atoms/cm².

By the ion beam irradiation of the exposed regions 2 the crystalline structure of the substrate material 1 in those regions 2 is transformed into an amorphous state.

FIG. 2 shows schematically a cross-section of a semiconductor device during a second process according to the present invention.

In the second process the implantation of the impurities as dopant to form doped regions 4 is carried out. The mask 3′ is used to delineate the regions 2 where implantation must be carried out. The dopant implantation process is schematically indicated by arrows IB_dopant.

The impurities which are implanted are chosen to obtain the desired conductivity type of the doped regions 4. The impurities (e.g., B, As, P, etc.) are implanted at low energy (typically less than 5 keV) and in a dose of approximately 1×10¹⁵ atoms/cm², in accordance with the desired characteristics of the junction to be formed.

FIG. 3 shows schematically a cross-section of a semiconductor device during a third process according to the present invention.

In the third process the silicidation regions are defined where a silicide layer is to be formed. A mask 3″ is formed which delineates the regions to be silicided. These silicidation regions may be regions 5 that overlap with doped regions 4, or it may be conduction regions 6 covering regions 2 which were only amorphised in the first process and not exposed in the second process of doped region formation. Such conduction regions 6 may be located at different locations than the dopant regions 4.

Also, the silicidation region may be a region 9 on top of a gate G. A gate 7 is schematically depicted here as a thin gate oxide layer 10, a poly-Si layer portion 7, and spacers 8. The top of the poly-Si layer portion 7 may have been pre-amorphised in the first process simultaneously with the junction regions 2, as will be appreciated by persons skilled in the art.

Next, a metal implantation process is performed for a metal chosen to form a metal-silicide (of a desired composition depending on the actual metal). Again an ion beam implantation process is carried out as schematically indicated by arrows IB_metal. Typical process parameters for the low energy process are: a beam energy between about I and about 20 keV, and a dose of approximately 1×10¹⁶-5×10¹⁷ atoms/cm². The metal can be chosen in accordance with the desired properties of the silicide (i.e., resistivity, work function, compatibility with further processing, etc.). Preferably, a metal may be chosen which may form a metal-silicide with a high Si: metal ratio, such as a metal-di-silicide, which requires a lower metal implant dose and simultaneously may offer a lower sheet resistance in comparison to other metal-silicide modifications of the same metal. The metal may be chosen from Co, Ni, Hf, Ti, Mo, W, or any other metal capable of forming a suitable silicide compound.

In the present invention, the choice of metal is not limited to metal-silicides which are epitaxial on the semiconductor substrate (e.g., silicon Si(100) or Si(111)).

It is noted that in the present invention the order of the second process of impurity implantation and the third process of metal implantation may be reversed.

FIG. 4 shows schematically a cross-section of a semiconductor device after a fourth process according to the present invention.

The fourth process encompasses a solid phase epitaxial regrowth (SPER) process. During a low temperature annealing process (e.g., rapid thermal annealing) at a relatively low annealing temperature of approx. 550 to approx. 750° C. during approx. 1 minute, the doped regions 5, 6 are epitaxially regrown with the same crystal structure as the semiconductor substrate layer 1. In the lower parts of the regions 5, activated junctions 11 of the conductivity type as defined by the implanted impurity are formed, in the upper part of the regions 5, 6 (closer to the surface) a silicide layer 12a, 12b, 13 is formed.

The silicide layer on top of a junction 11 may be formed as a silicide layer 12a adjacent to the spacers 8 of the gate G or as a remote silicide layer 12b in a region remote from the spacers 8. The silicide layer may also be formed as a single silicide layer 13 in an other substrate region 6 outside a junction region 5.

At the same time, silicide layer 14 may be formed in the top layer portion 9 of the gate G.

The definition of silicide layers 12a, 12b, 13, 14 is done by the mask used during the implantation step.

Further, an insulation layer 15 is shown in FIG. 4.

The silicide layer 12a and the remote silicide layer 12b are shown next to the gate G, but as will be appreciated by persons skilled in the art, instead of the gate G any other type of structural element such as LOCOS, a floating gate/control gate stack, etc. is also conceivable. The remote silicide layer 12b may even be formed in a junction area without any further structural element being present.

FIG. 5 shows schematically a cross-section of a semiconductor device in a further embodiment according to the present invention.

In the preceding FIGS. 1-4 the implantation of impurities into pre-defined regions 2 for forming dopant regions 5 and implantation of metal to form conducting layers 12a, 12b, 13 on dopant regions 5 or on other regions 6, was described for simply one impurity type and one metal. It is noted that the present invention allows the combination of multiple impurity implantation processes and multiple metal implantation processes. By multiple impurity implantation processes, dopant regions 5 of different conductivity type can be formed by using different impurities in the respective impurity implantation processes. Also, dopant regions 5 of equal conductivity type but with different impurity levels may be formed in this manner. It is only required to apply different masking layers in the respective impurity implantation processes.

Similarly, a combination of multiple metal implantation processes is possible on different areas of the semiconductor substrate. Again, appropriate masking should be used to define the respective areas. Moreover, the combination of multiple implantation processes allows to select a metal-silicide with a required work function for each area on the semiconductor substrate depending on the state of the respective area (e.g., a dopant region 5 of p-type, a dopant region 5 of n-type, a gate conduction region 9, or another conduction region 6).

In FIG. 5, an example is shown which comprises a first ultra-shallow junction 11 of a first conductivity type which is covered by a first silicide layer 12a, and a second ultra-shallow junction 17 of a second conductivity type, embedded in an insulating region 16 of opposite conductivity type.

The insulating region 16 may be formed in any way known to persons skilled in the art, including solid-phase epitaxial regrowth. Moreover, such embedded structures can be formed during a single pre-amorphisation step, multiple doping and single thermal budget corresponding to junction- and silicide-formation at the same time.

The second ultra-shallow junction 17 is covered by a second silicide layer 18. Further, a conduction region is shown which comprises a third silicide layer 19. Likewise, a fourth silicide layer may be present on a gate G (not shown). Each of the ultra-shallow junctions 11, 17 is formed by an impurity implantation process for the specific conductivity type as described above. Each of the suicide layers 12, 18, 19 is formed by a metal implantation process for the specific silicide as described above. The activation of the junctions 11, 17 and the formation of the silicide layers 12, 18, 19 is done simultaneously in the SPER process in the fourth process. Again, a remote silicide layer 12b and a single silicide layer 13 may be formed in these multiple implantation processes. The remote suicide layer 12b and the single silicide layer 13 may accordingly comprise multiple different metal silicides, which are each defined by the respective metal implantation process.

Finally, it is noted that in the case of creating a dopant region 5 with n-type conductivity by means of an ion beam process (IB_dopant) using As ions, the pre-amorphisation process (IB_pre) may be omitted due to self-amorphising properties of the As ion beam. In this case, the ion beam process for implanting the impurity element acts simultaneously as pre-amorphisation process (IB_pre).

1. Method of manufacturing a semiconductor device comprising the step of forming a metal-silicide layer on a semiconductor substrate,
said semiconductor substrate comprising at least a dopant region;
said dopant region comprising an ultra-shallow junction region;
said method comprising as a first step at least one impurity implantation process for forming said dopant region;
said method comprising as a second step at least one metal implantation process for forming said metal-silicide layer on said dopant region
characterized in that said method is arranged to carry out after said first and said second step:
as a third step a low-temperature annealing process wherein simultaneously said dopant region is activated and said metal-silicide layer is formed.

2. Method according to claim 1, wherein said method comprises a pre-amorphisation process by ion beam carried out as an initial process before said first step on at least said dopant region and said conduction region.

3. Method according to claim 1, wherein said at least one impurity implantation process comprises a first impurity implantation process using a first impurity to create a junction region of a first conductivity type.

4. Method according to claim 3, wherein said at least one impurity implantation process comprises a second impurity implantation process using a second impurity to create a junction region of a second conductivity type.

5. Method according to claim 3, wherein said at least one impurity implantation process comprises a second impurity implantation process using said first impurity to create a further junction region of said conductivity type with a different impurity level.

6. Method according to claim 3, wherein said at least one metal implantation process for forming said metal-silicide layer comprises a first metal implantation process using a first mask and a first metal to create a first silicide layer on said junction region of said first conductivity type.

7. Method according to claim 3, wherein said at least one metal implantation process for forming said metal-silicide layer comprises a second metal implantation process using a second mask and a second metal to create a second silicide layer on said junction region of said second conductivity type.

8. Method according to claim 3, wherein said at least one metal implantation process for forming said metal-silicide layer comprises a further metal implantation process using a further mask and a further metal to create a further silicide layer on said conduction region or said gate conduction region.

9. Method according to claim 1, wherein said method comprises in said second step said at least one metal implantation process for forming said metal-silicide layer on a conduction region.

10. Method according to claim 1 wherein said method comprises in said second step said at least one metal implantation process for forming said metal-silicide layer on a gate conduction region of a gate.

11. Method according to claim 1, wherein said low annealing temperature process is a solid-phase epitaxial regrowth process.

12. Method according to claim 1, wherein each of said first, second, or further metal is capable of forming a metal-di-silicide compound during said low temperature annealing process.

13. Method according to claim 1, wherein said metal silicide layer is formed as at least one of a metal silicide layer adjacent to another structural element arranged within said junction region, or a remote metal silicide layer in said junction region remote from said other structural element, and a single metal silicide layer in said conduction region outside of said junction region.

14. Semiconductor device on semiconductor substrate comprising at least a dopant region, said dopant region comprising an ultra-shallow junction region, wherein said semiconductor device is manufactured by a method of formation of a metal-silicide layer in accordance with claim 1.
